(19) United States
(12) Patent Application Publication
(10) Pub. No.: US 2023/0327036 A1
(43) Pub. Date: Oct. 12, 2023

(54) SOLAR CELL STRUCTURE AND FABRICATION METHOD THEREOF

(71) Applicant: TSEC Corporation, New Taipei City (TW)

(72) Inventors: Cheng-Wen Kuo, Kaohsiung City (TW); Yung-Chih Li, Hsinchu County (TW); Ying-Quan Wang, Hsinchu County (TW); Sheng-Kai Wu, Miaoli County (TW); Wen-Ching Chu, New Taipei City (TW); Ta-Ming Kuan, Hsinchu City (TW); Hung Cheng, Hsinchu County (TW); Jen-Ho Kang, Miaoli County (TW); Cheng-Yeh Yu, Hsinchu City (TW)

(73) Assignee: TSEC Corporation, New Taipei City (TW)

(21) Appl. No.: 18/206,630

(22) Filed: Jun. 7, 2023

Related U.S. Application Data
(63) Continuation-in-part of application No. 17/528,205, filed on Nov. 17, 2021.
Application No. 17/528,205 is a continuation-in-part of application No. 17/016,361, filed on Sep. 9, 2020, now abandoned.

(30) Foreign Application Priority Data
Jun. 4, 2020 (TW) 109118806
May 13, 2021 (TW) 110117278

(51) Int. Cl. H01L 31/054; H01L 31/0216; H01L 31/18

(52) U.S. Cl. CPC H01L 31/054; H01L 31/02168; H01L 31/18

(57) ABSTRACT

A solar cell structure includes a semiconductor substrate having a front side and a back side. A pyramid structure is disposed on the front side of the semiconductor substrate. The pyramid structure has an aspect ratio between 0.5-1.2. A front passivation layer is disposed on the pyramid structure. A first anti-reflection layer is disposed on the pyramid structure. The first anti-reflection layer is a multi-layered, graded anti-reflection layer having at least three coating layers. The at least three coating layers comprise a silicon oxynitride layer having a thickness of 15-30 nm and a refractive index between 1.65 and 1.75. The silicon oxynitride layer is an outermost layer of the multi-layered, graded anti-reflection layer.

### CROSS REFERENCE TO RELATED APPLICATIONS

This application is a continuation-in-part of U.S. application Ser. No. 17/528,205, filed on Nov. 17, 2021, which is a continuation-in-part of U.S. application Ser. No. 17/016,361, filed on Sep. 9, 2020. The contents of these applications are incorporated herein by reference.

### BACKGROUND OF THE INVENTION

### 1. Field of the Invention

The present invention relates to the technical field of solar cells, in particular to an improved crystalline silicon solar cell structure and a fabrication method thereof, which can reduce glare at different tilt angles, and is particularly suitable for application in the field of construction.

### 2. Description of the Prior Art

In recent years, under the global promotion of green energy, high expectations have been placed on the power supply of crystalline silicon solar cells, and they have been actively researched, developed and commercialized.

Currently, the crystalline silicon solar cells are mostly used in large-scale power plants, so only the appearance of the battery viewed at eye level is concerned. However, for solar power products used in buildings, the angle of use will be different from those used in general large power plants. For example, when solar cell panels are used in buildings, the glare caused by sunlight reflection must be reduced to avoid negative effects on the surrounding environment or car driving, and so on.

As shown in FIG. 1, if the crystalline silicon solar panels P are installed on the exterior wall of the building B, the sunlight SL generated by the sun S shines on the surface of the solar panels P has different reflectivities at different inclination angles (or tilt angles) Θ relative to the human eye HE. For example, when the tilt angle Θ=80 degrees, the reflectivity is about 11.66%, and when the tilt angle Θ=60 degrees, the reflectivity is about 13.60%, which produce glare and discomfort to the human eye.

It can be seen that when the crystalline silicon solar cell is applied to the exterior wall of a building, the glare caused by the above-mentioned reflection at different inclination angles still needs to be overcome. Therefore, there is still a need for an improved solar cell in this technical field, which has a design to reduce glare at different tilt angles.

### SUMMARY OF THE INVENTION

One object of the present invention is to provide an improved crystalline silicon solar cell structure and a manufacturing method thereof, which can reduce glare at different tilt angles, so that the crystalline silicon solar cell can be applied in the construction field.

One aspect of the invention provides a solar cell structure including a semiconductor substrate having a front side and a back side. A pyramid structure is disposed on the front side of the semiconductor substrate. The pyramid structure has an aspect ratio between 0.5-1.2. A front passivation layer is disposed on the pyramid structure. A first anti-reflection layer is disposed on the pyramid structure. The first anti-reflection layer is a multi-layered, graded anti-reflection layer having at least three coating layers. The at least three coating layers comprise a silicon oxynitride layer having a thickness of 15-30 nm and a refractive index between 1.65 and 1.75. The silicon oxynitride layer is an outermost layer of the multi-layered, graded anti-reflection layer. A front electrode is provided on the first anti-reflection layer. A rear passivation layer is provided on the back side of the semiconductor substrate. A second anti-reflection layer is disposed on the rear passivation layer. A back electrode is disposed on the second anti-reflection layer, wherein the first anti-reflection layer has a reflectivity less than 5% at atilt angle of 80°.

According to some embodiments, the semiconductor substrate comprises an N-type or P-type doped monocrystalline silicon substrate, or a monocrystalline silicon wafer.

According to some embodiments, the front passivation layer comprises a silicon dioxide layer.

According to some embodiments, the front passivation layer has a thickness of 5-15 nm and a refractive index between 1.45-1.5.

According to some embodiments, the at least three coating layers comprise a silicon nitride layer having a thickness of 40-90 nm and a refractive index graded from 2.5 to 2.0 across its thickness.

According to some embodiments, the rear passivation layer comprises a silicon oxynitride layer or an aluminum oxide layer.

According to some embodiments, the second anti-reflection layer comprises silicon nitride, silicon oxynitride, tungsten oxide or titanium dioxide.

According to some embodiments, the second anti-reflection layer has a thickness of about 10-300 nm.

According to some embodiments, a doped area is disposed on the front side of the semiconductor substrate.

According to some embodiments, the pyramid structure has a height of 0.8-1.2 μm and a bottom width of 1.0-1.5 micrometers.

Another aspect of the invention provides a method for forming a solar cell structure. A semiconductor substrate having a front side and a back side is provided. The front side of the semiconductor substrate is subjected to wet etching in alkaline solution containing potassium hydroxide and an additive capable of suppressing anisotropic etch rate of the alkaline solution, thereby forming a pyramid structure having an aspect ratio between 0.5-1.2. A front passivation layer is formed on the pyramid structure. A first anti-reflection layer is formed on the pyramid structure. The first anti-reflection layer is a multi-layered, graded anti-reflection layer having at least three coating layers. The at least three coating layers comprise a silicon oxynitride layer having a thickness of 15-30 nm and a refractive index between 1.65 and 1.75. The silicon oxynitride layer is an outermost layer of the multi-layered, graded anti-reflection layer. A front electrode is formed on the first anti-reflection layer. A rear passivation layer is formed on the back side of the semiconductor substrate. A second anti-reflection layer is formed on the rear passivation layer. A back electrode is formed on the second anti-reflection layer, wherein the first anti-reflection layer has a reflectivity less than 5% at a tilt angle of 80°.

According to some embodiments, the semiconductor substrate comprises an N-type or P-type doped monocrystalline silicon substrate, or a monocrystalline silicon wafer.

According to some embodiments, the front passivation layer comprises a silicon dioxide layer.

According to some embodiments, the front passivation layer has a thickness of 5-15 nm and a refractive index between 1.45-1.5.

According to some embodiments, the at least three coating layers comprise a silicon nitride layer having a thickness of 40-90 nm and a refractive index graded from 2.5 to 2.0 across its thickness.

According to some embodiments, the rear passivation layer comprises a silicon oxynitride layer or an aluminum oxide layer.

According to some embodiments, the second anti-reflection layer comprises silicon nitride, silicon oxynitride, tungsten oxide or titanium dioxide.

According to some embodiments, the second anti-reflection layer has a thickness of about 10-300 nm.

According to some embodiments, a doped area is disposed on the front side of the semiconductor substrate.

According to some embodiments, the pyramid structure has a height of 0.8-1.2 μm and a bottom width of 1.0-1.5 micrometers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates that the crystalline silicon solar panels are installed on the external wall of the building, wherein the sunlight illuminates the surface of the solar cell panel, which has different reflectivity at different tilt angles relative to the human eye.

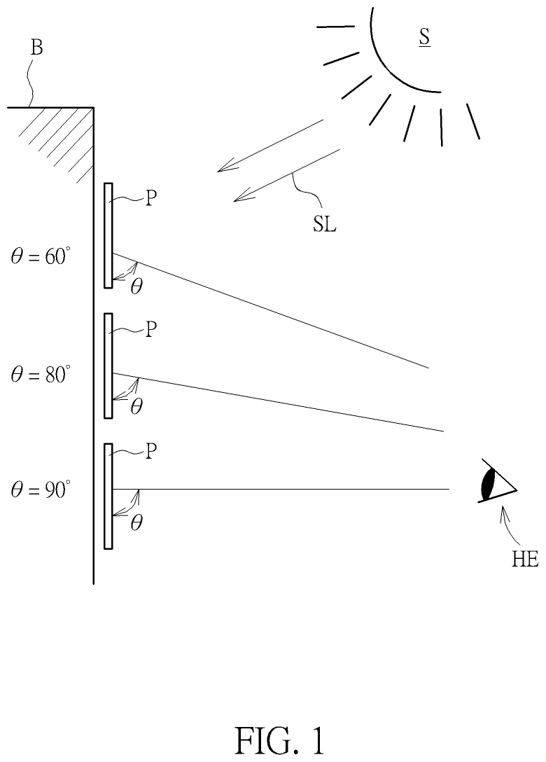

FIG. 2 is a schematic cross-sectional view of a solar cell structure according to an embodiment.

FIG. 3 illustrates a flow chart for manufacturing the solar cell structure.

FIG. 4 illustrates the structure of a finished solar cell in a cross-sectional view.

FIG. 5 shows the drop in reflectivity of the traditional solar cell and the reflectivity of the solar cell of the present invention under different tilt angles.

FIG. 6 is a plot of the reflectance drop versus tilt angle in FIG. 5.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized and structural, logical, and electrical changes may be made without departing from the scope of the present invention. Therefore, the following detailed description is not to be considered as limiting, but the embodiments included herein are defined by the scope of the accompanying claims.

Solar cell is a photoelectric element that combines P-type and N-type semiconductor materials to form the positive and negative electrodes. When the solar cell is irradiated by sunlight, it will absorb sunlight energy to generate electrons and holes. The positive charges (holes) and the negative charges (electrons) will move to the positive (P-type) and negative (N-type) directions respectively, generating a direct current. This type of photovoltaic element can convert light energy into electrical energy, so it is also called photovoltaic (PV).

Generally, the method for manufacturing a solar cell includes cleaning and roughening the surface of the wafer first, and then performing a diffusion process to form a phosphor glass layer and a doped emitter area on the wafer surface, and then removing the phosphor glass layer by an etching process. By using the screen printing technology, the electrode pattern is printed with metal paste on the front and back of the battery. By performing high-temperature sintering, the electrode is formed. Finally, the batteries (such as 6×10 or 6×12 arrays) are arranged and positioned on the glass substrate, and then stringer is performed, and the battery cells are connected in series to form solar modules through copper ribbon.

Since the current anti-reflection layer design of general solar cells has reached an optimized design, arbitrary changes may cause the photoelectric conversion efficiency of the solar cells to decline. The present invention therefore proposes an improved monocrystalline silicon solar cell structure and a manufacturing method thereof, which can reduce oblique angle glare without reducing the photoelectric conversion efficiency of the solar cell, so that the crystalline silicon solar cell is suitable for application in the construction field.

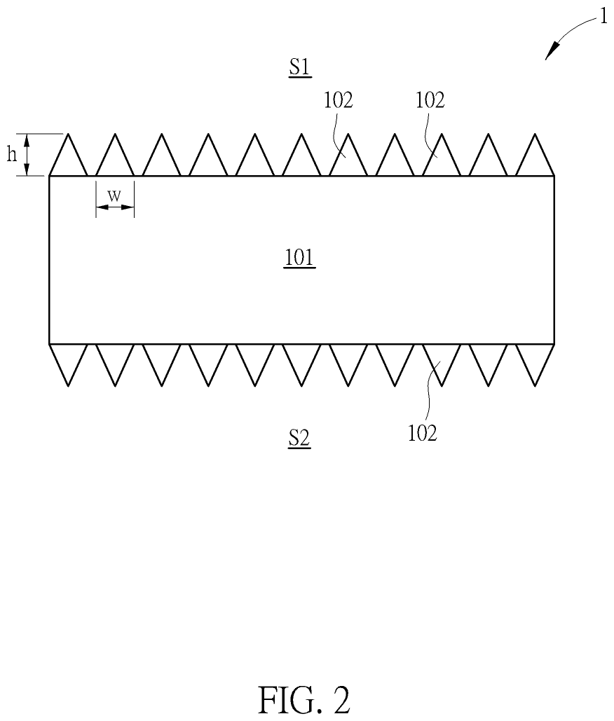

Please refer to FIG. 2, which is a schematic cross-sectional view of a solar cell structure having textured pyramids according to an embodiment. As shown in FIG. 2, the solar cell structure 1 includes a semiconductor substrate 101, such as an N-type or P-type doped monocrystalline silicon substrate or a monocrystalline silicon wafer, the thickness of which is, for example, about 60 to 200 micrometers (μm), but is not limited to this. On the front side (light-receiving side) S1 and the back side S2 of the semiconductor substrate 10, a surface roughening process is performed to form a plurality of pyramid structures 102, each of which has a height h of about 0.8 to 1.2 μm and a bottom width w of less than 1.5 μm, for example, 1.0-1.5 μm. In some embodiments, the bottom width w may range between 0.8-2.5 μm, preferably between 1.0-2.0 μm, and more preferably between 1.0-1.5 μm. According to an embodiment, an aspect ratio (a ratio of height to bottom width or h/w) of the pyramid structure 102 may range between 0.5-1.2.

Generally, before (or after) forming the pyramid structures 102, a wafer surface cleaning process may be performed to remove contaminants or cutting damage. According to an embodiment, the pyramid structures 102 may be formed by wet etching in alkaline solution containing, for example, potassium hydroxide (KOH) and an additive including, but not limited to, potassium sorbate, sodium acetate, and surface active agent, but it is not limited thereto. The alkaline solution may have a concentration between about 1 weight percent and about 15 weight percent of KOH to deionized water (DI) water, such as about 3 weight percent.

Potassium hydroxide (KOH) is generally preferred for surface texturing of silicon in photovoltaic industry. Alkaline etchants etch [100] silicon surfaces much quicker than [111] silicon surfaces, which is the basis for the anisotropic etching process used to make pyramid texture. However, the etch rate of [100] silicon surfaces is too high to form pyramid structures having the desired aspect ratio between 0.5-1.2 and bottom width less than 1.5 μm. By incorporating the additive, the anisotropic etching or etch rate of silicon <100> plane during the surface texturing process can be effectively suppressed, so as to achieve the desired pyramid size and surface microstructure.

According to an embodiment, for example, the additive may be commercially available product TS53 from Changzhou Shichuang Energy Co. Ltd. The composition of TS53 may include water (<80% by volume), potassium sorbate (1%-2% by volume), sodium acetate (2%-4% by volume), surface active agent (5%-10% by volume), defoaming agent (5%-7% by volume), others (<6% by volume).

According to an embodiment, after the pyramid structures 102 are formed, a cleaning process is performed.

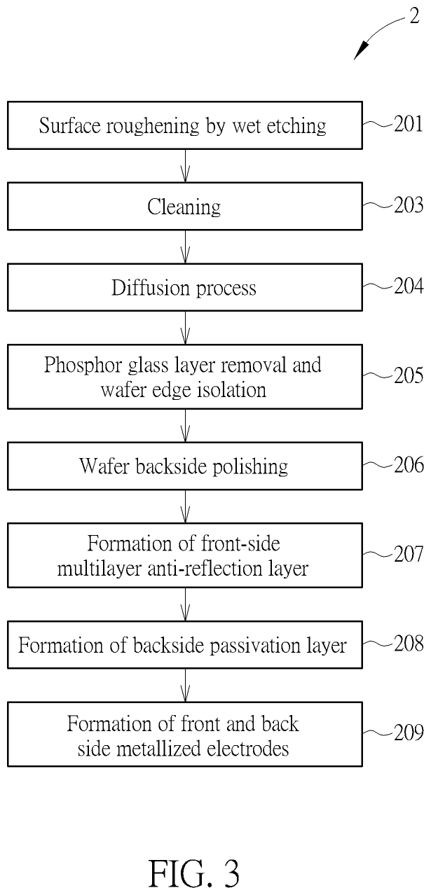

FIG. 3 illustrates a flow chart for manufacturing a solar cell structure. As shown in FIG. 3, the process 2 includes: after the surface roughening (Step 201) is completed, then the wafer surface is cleaned (Step 203), then the diffusion process (Step 204) is performed, and then the phosphor glass layer is removed and wafer edge isolation is performed (Step 205), then the backside of the wafer is polished (Step 206), and an anti-reflection layer is formed on the front side of the wafer (Step 207), a passivation layer is then formed on the backside of the wafer (Step 208), and then metallized electrodes are formed on the front and back sides of the wafer (Step 209).

As previously mentioned, the surface roughening process (Step 201) is preferably performed by wet etching in alkaline solution containing, for example, potassium hydroxide (KOH) and an additive that is capable of suppressing the anisotropic etch rate of the alkaline solution. According to an embodiment, the formed pyramid structure has a height h of 1-5 μm, a bottom width w of 0.8-2.5 μm, preferably, 1.0-2.0 μm, more preferably 1.0-1.5 μm, and an aspect ratio between 0.5-1.2.

According to an embodiment, after the backside polishing of the wafer (Step 206), the wafer can be sent to a high-temperature furnace to grow a SiO₂ layer having a thickness of 5-15 nm on the surface of the wafer at about 700-800° C., or use chemical solvent to perform surface cleaning and grow SiO₂ layer having a thickness of 5-15 nm on the wafer surface, or use atomic layer deposition (ALD) or chemical phase deposition (CVD) to form a front passivation layer 111 and an oxide layer 311 having a thickness of 5-15 nm on the wafer surfaces.

According to an embodiment, for example, the front passivation layer 111 may include Al₂O₃, SiN, SiO₂, SiON, TiO₂, and the oxide layer 311 may include Al₂O₃, SiN, SiO₂, SiON, and TiO₂.

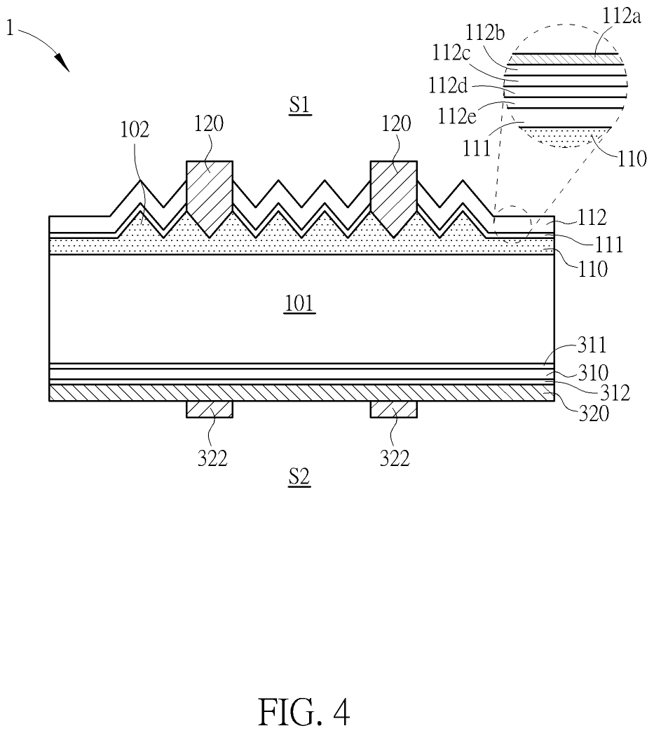

FIG. 4 illustrates the structure of a finished solar cell in a cross-sectional view. As shown in FIG. 4, the solar cell structure 1 has pyramid structures 102 on its front side S1. The pyramid structures 102 are preferably formed by wet etching in alkaline solution containing, for example, potassium hydroxide (KOH) and an additive that is capable of suppressing the anisotropic etch rate of the alkaline solution. The formed pyramid structure has a height h of 1-5 μm, a bottom width w of 0.8-2.5 μm, preferably, 1.0-2.0 μm, more preferably 1.0-1.5 μm, and an aspect ratio between 0.5-1.2.

According to an embodiment, the solar cell structure 1 has a doped region 110 formed on its front side S1. The doped area 110 can be formed by using a diffusion furnace to provide phosphorous chloride oxide (POCl₃) gas diffusion, and then using hydrofluoric acid (HF) and other wet etching methods to remove the phosphorus glass (PSG) (not shown) from the surface of the semiconductor substrate 101.

According to an embodiment, the solar cell structure 1 is further formed with a front passivation layer 111, for example, a silicon dioxide layer, on the front surface S1 of the solar cell structure 1. According to an embodiment, for example, the thickness of the front passivation layer 111 is 5-15 nm, and the refractive index of the front passivation layer 111 is between 1.45 and 1.5.

According to an embodiment, the solar cell structure 1 is further formed with a first anti-reflection layer 112 on the front side S1 of the solar cell structure 1, such as silicon nitride, silicon oxynitride, tungsten oxide, or titanium dioxide, but not limited thereto. The thickness of the first anti-reflective layer 112 may be between 40 nm and 120 nm.

According to an embodiment, the first anti-reflective layer 112 is a multi-layered, graded anti-reflective layer, for example, including at least a silicon nitride layer and an outermost silicon oxynitride layer. According to an embodiment, for example, the thickness of the silicon nitride layer of the anti-reflection layer 112 is between 40 nm and 90 nm, and the refractive index of the silicon nitride layer is graded or gradually changed from 2.5 to 2.0 across its thickness, for example, with a refractive index of 2.5 at the interface between the front passivation layer 111 and the silicon nitride layer and a refractive index of 2.0 at the interface between the silicon nitride layer and the outermost silicon oxynitride layer. According to an embodiment, for example, the thickness of the outermost silicon oxynitride layer of the anti-reflective layer 112 is between 15 nm and 30 nm, and the refractive index is between 1.65 and 1.75.

According to an embodiment, the first anti-reflection layer 112 is a multilayer, graded anti-reflection layer including at least three coating layers, for example, 3-10 layers, including, for example, silicon nitride, silicon oxynitride, tungsten oxide, titanium dioxide, or any combinations thereof, but is not limited thereto. Preferably, the first anti-reflective layer 112 comprises a silicon oxynitride layer that is disposed as the outermost or topmost layer of the first anti-reflection layer 112. The silicon oxynitride layer may have a thickness of 15-30 nm and a refractive index between 1.65 and 1.75. The refractive index of the silicon nitride layer is graded or gradually changed from 2.5 to 2.0 across its thickness, for example, with a refractive index of 2.5 at the interface between the front passivation layer 111 and the silicon nitride layer and a refractive index of 2.0 at the interface between the silicon nitride layer and the outermost silicon oxynitride layer.

For example, as shown in the enlarged view of FIG. 4, the first anti-reflection layer 112 is a multilayer, graded anti-reflection layer including five coating layers including, for example, four silicon nitride layers 112b-112e on the front passivation layer 111 and the outermost or topmost silicon oxynitride layer 112a on the four silicon nitride layers 112b-112e. The refractive index of the silicon nitride layers 112b-112e is graded or gradually changed from 2.5 to 2.0 across its thickness. For example, the silicon nitride layer 112e may have a refractive index of 2.5 and the silicon nitride layer 112b may have a refractive index of 2.0. The silicon nitride layers 112c, 112d may have a refractive index between 2.0-2.5.

According to an embodiment, the multilayer anti-reflection layer 112 may be formed by plasma enhanced chemical vapor deposition (PECVD) or low pressure chemical vapor deposition (LPCVD), but is not limited thereto.

According to an embodiment, the solar cell structure 1 further comprises a front metal electrode (or front electrode) 120 formed on the front side S1 of the solar cell structure 1, which can penetrate the first anti-reflective layer 112 by sintering, and is electrically connected to the doped region 110 below. The front metal electrode 120 can be formed by screen printing or the like.

According to an embodiment, the solar cell structure 1 further comprises a rear passivation layer 310 formed on the back side S2. For example, the rear passivation layer 310 may comprise silicon dioxide, aluminum oxide, silicon nitride, silicon oxynitride, titanium dioxide, or the like. For example, in a case that the rear passivation layer 310 is silicon dioxide, the rear passivation layer 310 may be formed by using a high temperature furnace tube at a high temperature of 700 to 800 degrees Celsius. In some embodiments, the rear passivation layer 310 may be formed by cleaning process wherein the silicon dioxide is grown using a chemical solvent. In some embodiments, the rear passivation layer 310 may be formed by using atomic layer deposition or chemical vapor deposition.

According to an embodiment, the solar cell structure 1 may optionally comprise a second anti-reflection layer 312 formed on its back side S2, such as silicon nitride, silicon oxynitride, tungsten oxide, or titanium dioxide, but it is not limited thereto. The thickness of the second anti-reflection layer 312 may be between 10 nm and 300 nm.

According to an embodiment, the solar cell structure 1 further comprises a back metal electrode (or back electrode) 320 and a pad (metal bonding pad) 322 formed on the back side S2. According to an embodiment, the back metal electrode 320 is formed on the second anti-reflection layer 312. The back metal electrode 320 can be formed by screen printing or the like. It should be noted that the above-mentioned process steps, sequences, and structures are only examples, and the technical means and methods used are only examples, and the film materials and process parameters are not limited to the above description.

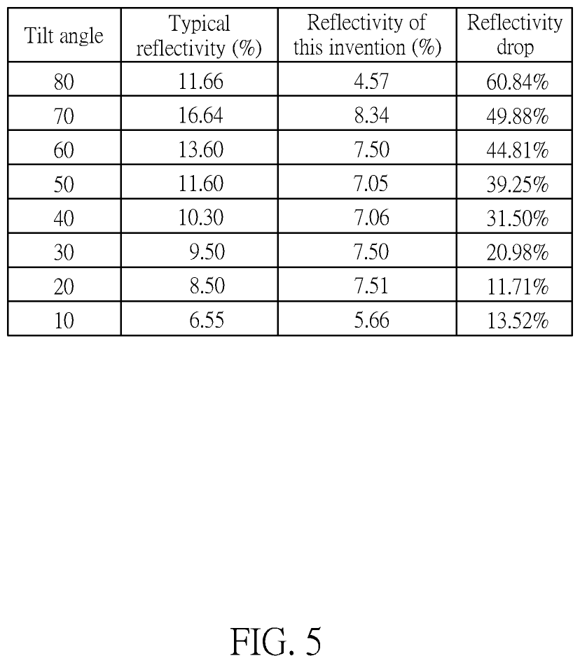

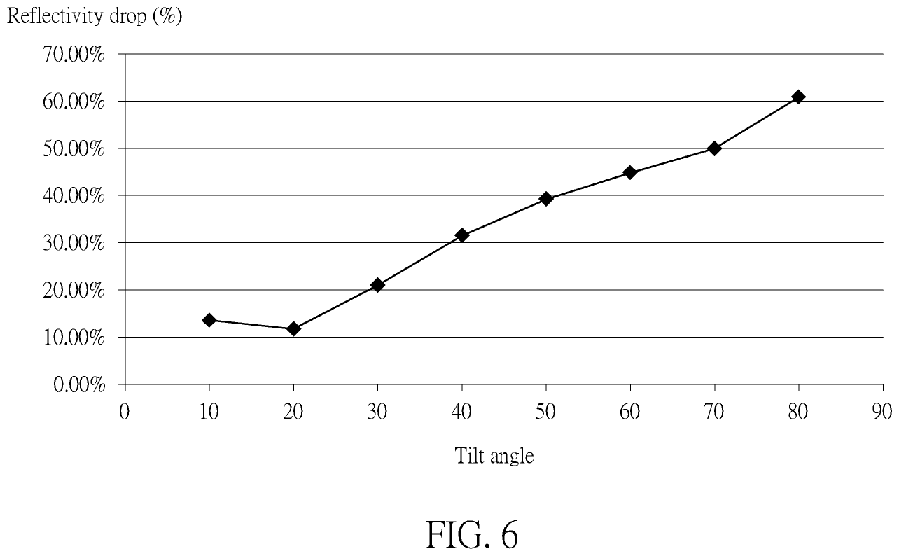

The invention utilizes a multi-layered (3-10 layers), graded anti-reflection layer formed on the front side of the solar cell structure, in combination with the pyramid structures featuring an aspect ratio between 0.5-1.2, which can reduce the visual difference in appearance under different tilt angles and reduce glare, so that the monocrystalline silicon solar cell can be applied in the construction field. From the measurement results in FIG. 5 and FIG. 6, it can be seen that when the tilt angle Θ=80 degrees, the first anti-reflection layer has a reflectivity less than 5%, and the reflectivity drop can reach 60.84%. When the tilt angle Θ=60 degrees, the reflectivity drop can also reach 44.81%, and the average reflectivity under different tilt angles can be less than 7%, which shows that the solar cell of the present invention can indeed reduce glare, and the effect is significant.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A solar cell structure, comprising:
a semiconductor substrate having a front side and a back side;
a pyramid structure disposed on the front side of the semiconductor substrate, wherein the pyramid structure has an aspect ratio between 0.5-1.2;
a front passivation layer disposed on the pyramid structure;
a first anti-reflection layer disposed on the pyramid structure, wherein the first anti-reflection layer is a multi-layered, graded anti-reflection layer having at least three coating layers, wherein the at least three coating layers comprise a silicon oxynitride layer having a thickness of 15-30 nm and a refractive index between 1.65 and 1.75, wherein the silicon oxynitride layer is an outermost layer of the multi-layered, graded anti-reflection layer;
a front electrode provided on the first anti-reflection layer;
a rear passivation layer provided on the back side of the semiconductor substrate;
a second anti-reflection layer disposed on the rear passivation layer; and
a back electrode disposed on the second anti-reflection layer, wherein the first anti-reflection layer has a reflectivity less than 5% at atilt angle of 80°.

2. The solar cell structure according to claim 1, wherein the semiconductor substrate comprises an N-type or P-type doped monocrystalline silicon substrate, or a monocrystalline silicon wafer.

3. The solar cell structure according to claim 1, wherein the front passivation layer comprises a silicon dioxide layer.

4. The solar cell structure according to claim 3, wherein the front passivation layer has a thickness of 5-15 nm and a refractive index between 1.45-1.5.

5. The solar cell structure according to claim 1, wherein the at least three coating layers comprise a silicon nitride layer having a thickness of 40-90 nm and a refractive index graded from 2.5 to 2.0 across its thickness.

6. The solar cell structure according to claim 1, wherein the rear passivation layer comprises a silicon oxynitride layer or an aluminum oxide layer.

7. The solar cell structure according to claim 1, wherein the second anti-reflection layer comprises silicon nitride, silicon oxynitride, tungsten oxide or titanium dioxide.

8. The solar cell structure according to claim 1, wherein the second anti-reflection layer has a thickness of about 10-300 nm.

9. The solar cell structure according to claim 1, wherein a doped area is disposed on the front side of the semiconductor substrate.

10. The solar cell structure according to claim 1, wherein the pyramid structure has a height of 0.8-1.2 μm and a bottom width of 1.0-1.5 micrometers.

11. A method for forming a solar cell structure, comprising:
providing a semiconductor substrate having a front side and a back side;
subjecting the front side of the semiconductor substrate to wet etching in alkaline solution containing potassium hydroxide and an additive capable of suppressing anisotropic etch rate of the alkaline solution, thereby forming a pyramid structure having an aspect ratio between 0.8-1.2;
forming a front passivation layer on the pyramid structure;
forming a first anti-reflection layer on the pyramid structure, wherein the first anti-reflection layer is a multi-layered, graded anti-reflection layer having at least three coating layers, wherein the at least three coating layers comprise a silicon oxynitride layer having a thickness of 15-30 nm and a refractive index between 1.65 and 1.75, wherein the silicon oxynitride layer is an outermost layer of the multi-layered, graded anti-reflection layer;
forming a front electrode on the first anti-reflection layer;
forming a rear passivation layer on the back side of the semiconductor substrate;
forming a second anti-reflection layer on the rear passivation layer; and
forming a back electrode on the second anti-reflection layer, wherein the first anti-reflection layer has a reflectivity less than 5% at a tilt angle of 80°.

12. The method according to claim 11, wherein the semiconductor substrate comprises an N-type or P-type doped monocrystalline silicon substrate, or a monocrystalline silicon wafer.

13. The method according to claim 11, wherein the additive comprises potassium sorbate, sodium acetate, and surface active agent.

14. The method according to claim 11, wherein the front passivation layer comprises a silicon dioxide layer and has a thickness of 5-15 nm and a refractive index between 1.45-1.5.

15. The method according to claim 11, wherein the at least three coating layers comprise a silicon nitride layer having a thickness of 40-90 nm and a refractive index graded from 2.5 to 2.0 across its thickness.

16. The method according to claim 11, wherein the rear passivation layer comprises a silicon oxynitride layer or an aluminum oxide layer.

17. The method according to claim 11, wherein the second anti-reflection layer comprises silicon nitride, silicon oxynitride, tungsten oxide or titanium dioxide.

18. The method according to claim 11, wherein the second anti-reflection layer has a thickness of about 10-300 nm.

19. The method according to claim 11, wherein a doped area is disposed on the front side of the semiconductor substrate.

20. The method according to claim 11, wherein the pyramid structure has a height of 1-5 μm and a bottom width of 1.0-1.5 micrometers.
